(19) United States
(12) Patent Application Publication
(10) Pub. No.: US 2025/0294829 A1
(43) Pub. Date: Sep. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takahiro Kato, Shinagawa Tokyo (JP); Tatsunori Sakano, Shinagawa Tokyo (JP); Ryohei Gejo, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/032,531

(22) Filed: Jan. 21, 2025

(30) Foreign Application Priority Data
Mar. 13, 2024 (JP) 2024-039149

(51) Int. Cl. H10D 62/10; H10D 12/00

(52) U.S. Cl. CPC H10D 62/124; H10D 12/441

(57) ABSTRACT

According to one embodiment, a semiconductor device includes a first element, a second element, a first terminal, a second terminal, a third terminal, a fourth terminal, a fifth terminal, a sixth terminal, and a circuit section. Each of the first element and the second element includes a first electrode, a second electrode, a third electrode, a fourth electrode, and a semiconductor member. The semiconductor member includes a first semiconductor region of a first conductivity type, a second semiconductor region of the first conductivity type, a third semiconductor region of a second conductivity type, a fourth semiconductor region of the second conductivity type, a fifth semiconductor region of the first conductivity type, and a sixth semiconductor region of the second conductivity type. The first semiconductor region includes a first partial region, a second partial region, a third partial region, and a fourth partial region.

### CROSS-REFERENCE TO RELATED APPLICATIONS

This application is based upon and claims the benefit of priority from Japanese Patent Application No. 2024-039149, filed on Mar. 13, 2024; the entire contents of which are incorporated herein by reference.

### FIELD

Embodiments described herein relate generally to a semiconductor device.

### BACKGROUND

For example, semiconductor devices such as IGBTs (insulated gate bipolar transistors) are used in power conversion circuits and the like. Reduction of loss is desired.

### BRIEF DESCRIPTION OF THE DRAWINGS

FIGS. 1A to 1D are schematic diagrams illustrating an operation of a semiconductor device according to a first embodiment;

FIG. 2 is a schematic cross-sectional view illustrating the semiconductor device according to the first embodiment;

FIG. 3 is a schematic cross-sectional view illustrating the semiconductor device according to the first embodiment;

FIG. 4 is an equivalent circuit illustrating the semiconductor device according to the first embodiment; and

FIGS. 5A to 5D are schematic diagrams illustrating an operation of the semiconductor device according to the first embodiment.

### DETAILED DESCRIPTION

According to one embodiment, a semiconductor device includes a first element, a second element, a first terminal, a second terminal, a third terminal, a fourth terminal, a fifth terminal, a sixth terminal, and a circuit section. Each of the first element and the second element includes a first electrode, a second electrode, a third electrode, a fourth electrode, and a semiconductor member. The semiconductor member is provided between the first electrode and the second electrode. A second direction from the third electrode to the fourth electrode crosses a first direction from the first electrode to the second electrode. The semiconductor member includes a first semiconductor region of a first conductivity type, a second semiconductor region of the first conductivity type, a third semiconductor region of a second conductivity type, a fourth semiconductor region of the second conductivity type, a fifth semiconductor region of the first conductivity type, and a sixth semiconductor region of the second conductivity type. The first semiconductor region includes a first partial region, a second partial region, a third partial region, and a fourth partial region. A direction from the first partial region to the third electrode is along the first direction. A direction from the second partial region to the fourth electrode is along the first direction. The second semiconductor region is connected to the second electrode. A direction from a part of the third electrode to the second semiconductor region is along the second direction. A part of the third semiconductor region is between the third partial region and the second semiconductor region in the first direction. A direction from the part of the third electrode to the part of the third semiconductor region is along the second direction. Another part of the third semiconductor region is between the fourth partial region and the fourth semiconductor region in the first direction. A direction from the other part of the third semiconductor region to a part of the fourth electrode is along the second direction. The fifth semiconductor region is provided between the first electrode and the first semiconductor region in the first direction. The sixth semiconductor region is provided between the first electrode and the first semiconductor region in the first direction. A direction from the fifth semiconductor region to the sixth semiconductor region is along a fourth direction. The fourth direction is along a plane including the second direction and a third direction. The third direction crosses a plane including the first direction and the second direction. The first terminal is electrically connected to the second electrode of the first element. The second terminal is electrically connected to the third electrode of the first element. The third terminal is electrically connected to the fourth electrode of the first element. The fourth terminal is electrically connected to the second electrode of the second element and the first electrode of the first element. The fifth terminal is electrically connected to the third electrode of the second element. The sixth terminal is electrically connected to the fourth electrode of the second element. The circuit section is configured to set the second terminal to a first potential based on a potential of the first terminal in a first period. The circuit section is configured to set the second terminal to a third potential based on the potential of the first terminal in a second period after the first period. The circuit section is configured to set the second terminal to a second potential based on the potential of the first terminal in a third period after the second period. The second potential is lower than the first potential. The third potential is between the first potential and the second potential. The circuit section is configured to set the third terminal to the first potential in the first period and the second period. The circuit section is configured to set the third terminal to the second potential in the third period. The circuit section is configured to set the fifth terminal and the sixth terminal to a fourth potential based on a potential of the fourth terminal in the first period and the second period. The circuit section is configured to set the fifth terminal and the sixth terminal to a fifth potential based on the potential of the fourth terminal in the third period. The fourth potential is lower than the fifth potential.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

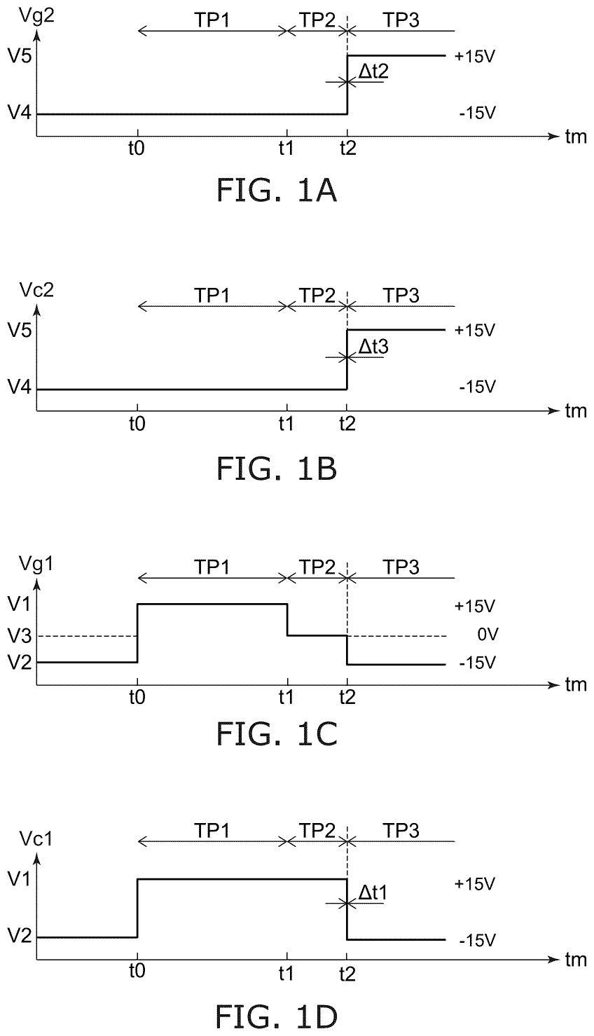

FIGS. 1A to 1D are schematic diagrams illustrating an operation of a semiconductor device according to a first embodiment.

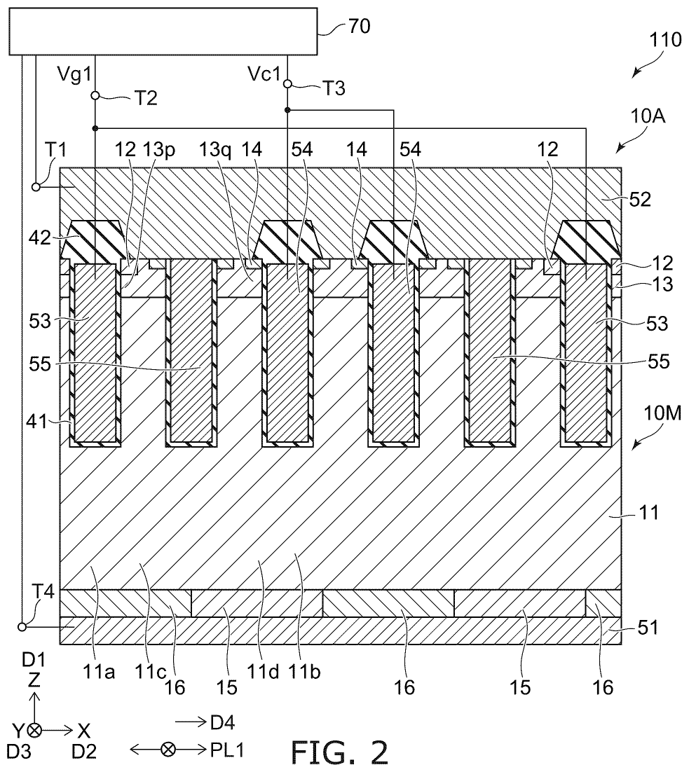

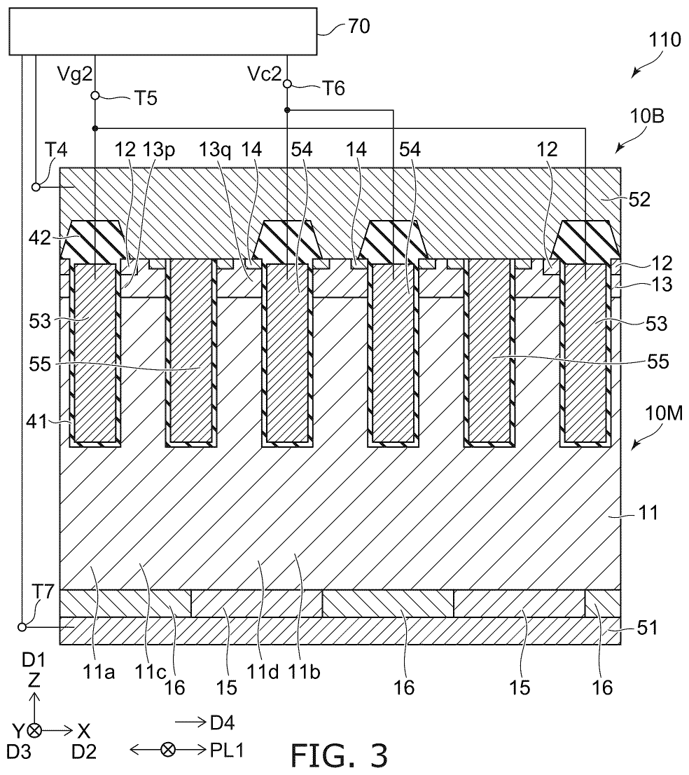

FIGS. 2 and 3 are schematic cross-sectional views illustrating the semiconductor device according to the first embodiment.

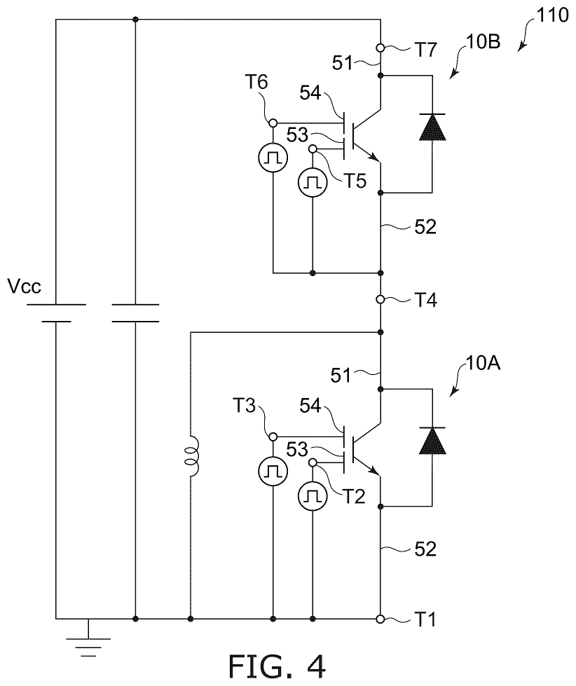

FIG. 4 is an equivalent circuit illustrating the semiconductor device according to the first embodiment.

As shown in FIGS. 2 and 3, a semiconductor device 110 according to the embodiment includes a first element 10A, a second element 10B, a first terminal T1, a second terminal T2, a third terminal T3, a fourth terminal T4, a fifth terminal T5, a sixth terminal T6, and a circuit section 70.

Each of the first element 10A and the second element 10B includes a first electrode 51, a second electrode 52, a third electrode 53, a fourth electrode 54, and a semiconductor member 10M. The semiconductor member 10M is provided between the first electrode 51 and the second electrode 52.

A second direction D2 from the third electrode 53 to the fourth electrode 54 crosses a first direction D1 from the first electrode 51 to the second electrode 52. The first direction D1 is defined as a Z-axis direction. One direction perpendicular to the Z-axis direction is defined as an X-axis direction. A direction perpendicular to the Z-axis direction and the X-axis direction is defined as a Y-axis direction. The second direction D2 may be, for example, the X-axis direction.

For example, the third electrode 53 and the fourth electrode 54 may extend along a third direction D3. The third direction D3 crosses a plane including the first direction D1 and the second direction D2. The third direction D3 may be, for example, the Y-axis direction.

The semiconductor member 10M includes a first semiconductor region 11, a second semiconductor region 12, a third semiconductor region 13, a fourth semiconductor region 14, a fifth semiconductor region 15, and a sixth semiconductor region 16. The semiconductor member 10M may include silicon, for example. The semiconductor member 10M may include a compound semiconductor. The compound semiconductor may include Ga and N, for example. The compound semiconductor may include silicon carbide, for example. The semiconductor member 10M extends along the second direction D2 and the third direction D3.

The first semiconductor region 11 is of a first conductivity type. The first conductivity type is one of n-type and p-type. In the following, the first conductivity type is n-type.

The first semiconductor region 11 includes a first partial region 11a, a second partial region 11b, a third partial region 11c, and a fourth partial region 11d. A direction from the first partial region 11a to the third electrode 53 is along the first direction D1. A direction from the second partial region 11b to the fourth electrode 54 is along the first direction D1.

The region overlapping the third electrode 53 in the Z-axis direction corresponds to the first partial region 11a. The first partial region 11a is located between the third electrode 53 and the first electrode 51. The region overlapping the fourth electrode 54 in the Z-axis direction corresponds to the second partial region 11b. The second partial region 11b is located between the third electrode 53 and the first electrode 51. The boundaries between the first partial region 11a, the second partial region 11b, the third partial region 11c, and the fourth partial region 11d may be clear or unclear.

A direction from a part of the third electrode 53 to a part of the first semiconductor region 11 is along the second direction D2. A direction from a part of the fourth electrode 54 to a part of the first semiconductor region 11 is along the second direction D2. A direction from a part of the first insulating member 41 to a part of the third partial region 11c is along the second direction D2. A part of the first insulating member 41 that is in contact with the third electrode 53 is in contact with a part of the third partial region 11c. A direction from a part of the first insulating member 41 to a part of the fourth partial region 11d is along the second direction D2. A part of the first insulating member 41 that is in contact with the fourth electrode 54 is in contact with a part of the fourth partial region 11d.

The second semiconductor region 12 is of the first conductivity type. A direction from a part of the third electrode 53 to the second semiconductor region 12 is along the second direction D2. For example, the second semiconductor region 12 is provided between the first electrode 51 and the second electrode 52 in the first direction D1. The second semiconductor region 12 is in contact with a part of the first insulating member 41 that is in contact with the third electrode 53. The second semiconductor region 12 is in contact with the second electrode 52.

The third semiconductor region 13 is of a second conductivity type. The second conductivity type is the other of n-type and p-type. In the following, the second conductivity type is p-type. The third semiconductor region 13 may be connected to the second electrode 52. A boundary between the third semiconductor region 13 and the first semiconductor region 11 is in contact with the first insulating member 41. A portion 13p of the third semiconductor region 13 is located between the third partial region 11c and the second semiconductor region 12 in the first direction D1. A direction from a part of the third electrode 53 to the portion 13p of the third semiconductor region 13 is along the second direction D2. In the first semiconductor region 11, a region that overlaps the second semiconductor region 12 in the first direction D1 corresponds to the third partial region 11c. The portion 13p of the third semiconductor region 13 is in contact with a part of the first insulating member 41 that is in contact with the third electrode 53.

The fourth semiconductor region 14 is of the second conductivity type. Another portion 13q of the third semiconductor region 13 is located between the fourth partial region 11d and the fourth semiconductor region 14 in the first direction D1. A direction from the other portion 13q of the third semiconductor region 13 to a part of the fourth electrode 54 is along the second direction D2. In the first semiconductor region 11, a region that overlaps the fourth semiconductor region 14 in the first direction D1 corresponds to the fourth partial region 11d. For example, the fourth semiconductor region 14 is provided between the first semiconductor region 11 and the second electrode 52 in the first direction D1. The other portion 13q of the third semiconductor region 13 is in contact with a part of the first insulating member 41 that is in contact with the fourth electrode 54. The fourth semiconductor region 14 is in contact with a part of the first insulating member 41 that is in contact with the fourth electrode 54. The fourth semiconductor region 14 is in contact with the second electrode 52.

The fifth semiconductor region 15 is provided between the first electrode 51 and the first semiconductor region 11 in the first direction D1. The fifth semiconductor region 15 is of the first conductivity type.

The sixth semiconductor region 16 is provided between the first electrode 51 and the first semiconductor region 11 in the first direction D1. The sixth semiconductor region 16 is of the second conductivity type. A direction from the fifth semiconductor region 15 to the sixth semiconductor region 16 is along a fourth direction D4. The fourth direction D4 is along the plane PL1 including the second direction D2 and the third direction D3. The fourth direction D4 is, for example, along the second direction D2.

A plurality of the fifth semiconductor regions 15 and a plurality of the sixth semiconductor regions 16 may be provided. The fifth semiconductor region 15 and the sixth semiconductor region 16 may be provided alternately. The fifth semiconductor region 15 and the sixth semiconductor region 16 are in contact with the first electrode 51.

As shown in FIG. 2, the first terminal T1 is electrically connected to the second electrode 52 of the first element 10A. The second terminal T2 is electrically connected to the third electrode 53 of the first element 10A. The third terminal T3 is electrically connected to the fourth electrode 54 of the first element 10A.

As shown in FIGS. 2 and 3, the fourth terminal T4 is electrically connected to the second electrode 52 of the second element 10B and the first electrode 51 of the first element 10A. The second electrode 52 of the second element 10B is electrically connected to the first electrode 51 of the first element 10A.

As shown in FIG. 3, the fifth terminal T5 is electrically connected to the third electrode 53 of the second element 10B. The sixth terminal T6 is electrically connected to the fourth electrode 54 of the second element 10B.

In the first element 10A and the second element 10B, the current flowing between the first electrode 51 and the second electrode 52 is controlled by a potential of the third electrode 53 and a potential of the fourth electrode 54. The first electrode 51 functions, for example, as a collector electrode. The second electrode 52 functions, for example, as an emitter electrode. The third electrode 53 functions, for example, as a first gate electrode.

The fourth electrode 54 functions, for example, as a second gate electrode. The third electrode 53 functions, for example, as a main gate. The fourth electrode 54 functions, for example, as a control gate electrode.

The semiconductor device 110 is, for example, a double-gate RC-IEGT (Reverse-Conducting Injection Enhanced Gate Transistor).

The circuit section 70 is electrically connected to the first terminal T1, the second terminal T2, the third terminal T3, the fourth terminal T4, the fifth terminal T5, and the sixth terminal T6. The circuit section 70 is configured to control the potential of each of these terminals.

FIG. 1A illustrates the potential Vg2 of the fifth terminal T5 of the second element 10B. FIG. 1B illustrates the potential Vc2 of the sixth terminal T6 of the second element 10B. FIG. 1C illustrates the potential Vg1 of the second terminal T2 of the first element 10A. FIG. 1D illustrates the potential Vc1 of the third terminal T3 of the first element 10A. The horizontal axis of these figures is time tm.

As shown in FIG. 1C, the circuit section 70 is configured to set the second terminal T2 to a first potential V1 in a first period TP1. The first potential V1 is a potential based on the potential of the first terminal T1. The circuit section 70 is configured to set the second terminal T2 to a third potential V3 in a second period TP2 after the first period TP1. The third potential V3 is a potential based on the potential of the first terminal T1.

The circuit section 70 is configured to set the second terminal T2 to a second potential V2 in a third period TP3 after the second period TP2. The second potential V2 is a potential based on the potential of the first terminal T1. The second potential V2 is lower than the first potential V1. The third potential V3 is between the first potential V1 and the second potential V2.

In one example, the first potential V1 is +15V. In one example, the second potential V2 is −15V. In one example, the third potential V3 may be, for example, OV.

As shown in FIG. 1D, the circuit section 70 is configured to set the third terminal T3 to the first potential V1 in the first period TP1 and the second period TP2. The circuit section 70 is configured to set the third terminal T3 to the second potential V2 in the third period TP3.

As shown in FIGS. 1A and 1B, the circuit section 70 is configured to set the fifth terminal T5 and the sixth terminal T6 to a fourth potential V4 in the first period TP1 and the second period TP2. The fourth potential V4 is a potential based on the potential of the fourth terminal T4. The circuit section 70 is configured to set the fifth terminal T5 and the sixth terminal T6 to a fifth potential V5 in the third period TP3. The fifth potential V5 is a potential based on the potential of the fourth terminal T4. The fourth potential V4 is lower than the fifth potential V5. The value of the fourth potential V4 may be the same as the value of the second potential V2. The value of the fifth potential V5 may be the same as the value of the first potential V1. For example, the fifth potential V5 is positive, and the fourth potential V4 is negative.

For example, before the first period TP1, the first element 10A is in the steady ON state. In the first period TP1, the first element 10A is in the diode mode. The first period TP1 corresponds to, for example, an electron extraction period. The second period TP2 corresponds to a transition period (dead time) of mode switching. In the third period TP3, the first element 10A is in the reverse recovery mode. On the other hand, in the first period TP1 and the second period TP2, the second element 10B is in the OFF state. For example, in the third period TP3, the second element 10B operates in the IEGT mode. At the second time t2, the second element 10B starts to be turned on.

In the embodiment, in the second period TP2, the potential Vg1 of the second terminal T2 of the first element 10A is set to the third potential V3 being intermediate. Thus, the first element 10A functions as a low-injection diode. Thereby, the diode operation of high injection is suppressed in the transition period (dead time) of mode switching. For example, reverse recovery is performed in a state in which carriers are reduced. Thus, the reverse recovery loss Err can be reduced. According to the embodiment, a semiconductor device capable of reducing loss can be provided.

As described above, the fourth electrode 54 is provided with the fourth semiconductor region 14 of the first conductivity type instead of the second semiconductor region 12 of the first conductivity type. Thus, in the second period TP2, even when the potential Vc1 of the third terminal T3 (fourth electrode 54) is the first potential V1, electrons are suppressed from moving toward the second electrode 52 in the vicinity of the fourth electrode 54.

In the embodiment, after the potential Vg1 of the second terminal T2 (third electrode 53) decreases from the first potential V1, the potential Vg2 of the fifth terminal T5 and the potential Vc2 of the sixth terminal T6 change from the fourth potential V4 to the fifth potential V5. Thereby, the first terminal T1 and the seventh terminal T7 are not substantially short-circuited. Destruction of the element due to a short circuit is suppressed.

For example, in a first reference example, in the first period TP1, the potential Vg1 of the second terminal T2 (third electrode 53) and the potential Vc1 of the third terminal T3 (fourth electrode 54) are the first potential V1. In the second period TP2 and the third period TP3, these potentials are the second potential V2. On the other hand, in the first period TP1 and the second period TP2, the potential Vg2 of the fifth terminal T5 (the third electrode 53) and the potential Vc2 of the sixth terminal T6 (the fourth electrode 54) are the fourth potential V4. In the third period TP3, these potentials become the fifth potential V5. In such a first reference example, reverse recovery is performed in a state where there are many carriers. Therefore, the reverse recovery loss Err is large.

For example, in a second reference example, the second semiconductor region 12 of the first conductivity type is provided on the side portion of the fourth electrode 54 instead of the fourth semiconductor region 14 of the second conductivity type. Further, in the second reference example, in the second period TP2, the potential Vc1 of the third terminal T3 (fourth electrode 54) becomes the second potential V2. Except for this, the change in potential in the second reference example is the same as the change in potential in the semiconductor device 110. In the second reference example, reverse recovery is performed in a state in which there are many carriers in the vicinity of the fourth electrode 54 of the first element 10A. Therefore, there is a limit to reduce the reverse recovery loss Err.

When the reverse recovery loss Err in the first reference example is 1, the reverse recovery loss Err in the second reference example is 0.947. When the reverse recovery loss Err in the first reference example is 1, the reverse recovery loss Err in the semiconductor device 110 according to the embodiment is 0.918. As described above, according to the embodiment, the loss can be suppressed.

As shown in FIG. 3, the semiconductor device 110 may further include a seventh terminal T7. The seventh terminal T7 is electrically connected to the first electrode 51 of the second element 10B.

As shown in FIG. 4, the circuit section 70 is configured to apply a controlled voltage Vcc between the first terminal T1 and the seventh terminal T7.

In the embodiment, for example, the third potential V3 may be less than the threshold voltage of the first element 10A. In the embodiment, the third potential V3 may be a substantially intermediate value between the first potential V1 and the second potential V2. For example, a first absolute value of a first difference between the third potential V3 and the first potential V1 may be not less than 0.8 times and not more than 1.2 times a second absolute value of a second difference between the third potential V3 and the second potential V2. In the embodiment, for example, the first potential V1 is positive. The second potential V2 is negative.

In the embodiment, a second length of the second period TP2 is shorter than a first length of the first period TP1. For example, the second length may be not less than 10 times and not more than 100 times the first length. For example, the first length may be not less than 10 μs and not more than 200 μs. For example, the second length may be not less than 1 μs and less than 10 μs.

As shown in FIGS. 1C and 1D, the first period TP1 is a period from time t0 to first time t1. The second period TP2 is a period from the first time t1 to the second time t2. The third period TP3 is a period after the second time t2.

As shown in FIG. 1C, the circuit section 70 may be configured to change the potential Vg1 of the second terminal T2 from the first potential V1 toward the second potential V2 from the first time t1. As described above, the first potential V1 is a potential based on the potential of the first terminal T1. The second potential V2 is a potential based on the potential of the first terminal T1. The second potential V2 is lower than the first potential V1. The circuit section 70 is configured to set the potential Vg1 of the second terminal T2 to the second potential V2 at the second time t2 after the first time t1.

As shown in FIG. 1D, the circuit section 70 is configured to change the potential Vc1 of the third terminal T3 from the first potential V1 to the second potential V2 at the second time t2.

As shown in FIGS. 1A and 1B, the circuit section 70 is configured to change the potential Vg2 of the fifth terminal T5 and the potential Vc2 of the sixth terminal T6 from the fourth potential V4 to the fifth potential V5 at the second time t2.

The time period (second period TP2) between the first time t1 and the second time t2 is longer than the time At1 of the change from the first potential V1 to the second potential V2 in the potential Vc1 of the third terminal T3. The time period (second period TP2) between the first time t1 and the second time t2 is longer than the time (time At2 and time At3) of the change from the fourth potential V4 to the fifth potential V5 in the potential Vg2 of the fifth terminal T5 and the potential Vc2 of the sixth terminal T6. For example, the first period TP1 is longer than the second period TP2. The gradient (dV/dt) of the change in the potential Vg1 of the second terminal T2 in the period between the time to and the first time t1 is smaller than the value of the gradient of the change in the potential Vg1 of the second terminal T2 at the first time t1. The gradient (dV/dt) of the change in the potential Vg1 of the second terminal T2 in the period between the first time t1 and the second time t2 is smaller than the gradient of the change in the potential Vg1 of the second terminal T2 at the first time t1. The gradient of the change in the potential Vg1 of the second terminal T2 in the period between the first time t1 and the second time t2 is smaller than the gradient of the change in the potential Vg1 of the second terminal T2 at the second time t2.

In the example shown in FIGS. 1A to 1D, the time when the fifth terminal T5 and the sixth terminal T6 become the fifth potential V5 is the same as the time when the third terminal T3 becomes the second potential V2.

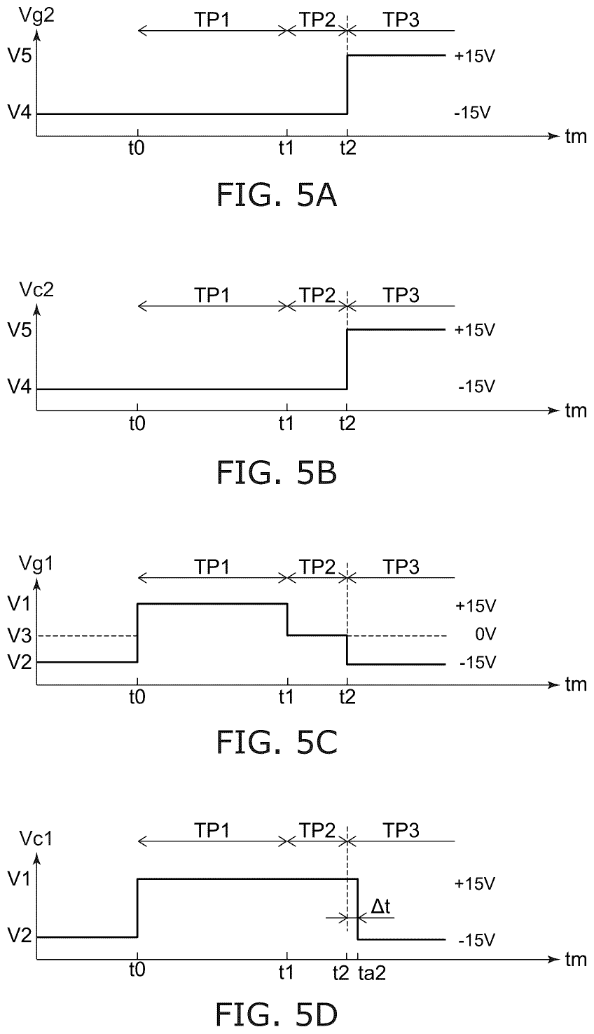

FIGS. 5A to 5D are schematic diagrams illustrating an operation of the semiconductor device according to the first embodiment.

These figures show another example of the operation in the semiconductor device 110. In the examples of FIG. 5A to FIG. 5D, the third terminal T3 becomes the second potential V2 after the time (second time t2) when the fifth terminal T5 and the sixth terminal T6 become the fifth potential V5. The time Δt between the time (second time t2) when the fifth terminal T5 and the sixth terminal T6 become the fifth potential V5 and the time ta2 when the third terminal T3 becomes the second potential V2 is 1 μs or less. Thereby, the time ta2 may be after the second time t2. By the difference between these times being as short as 1 μs or less, for example, loss can be suppressed.

As shown in FIGS. 2 and 3, for example, each of the first element 10A and the second element 10B may further include a first insulating member 41. The first insulating member 41 of the first element 10A is provided between the third electrode 53 of the first element 10A and the semiconductor member 10M of the first element 10A and between the fourth electrode 54 of the first element 10A and the semiconductor member 10M of the first element 10A.

The first insulating member 41 of the second element 10B is provided between the third electrode 53 of the second element 10B and the semiconductor member 10M of the second element 10B, and between the fourth electrode 54 of the second element 10B and the semiconductor member 10M of the second element 10B.

For example, a part of the first insulating member 41 contacts a part of the third electrode 53 and the second semiconductor region 12 in the second direction D2. Another part of the first insulating member 41 contacts a part of the fourth electrode 54 and the fourth semiconductor region 14 in the second direction D2.

As shown in FIGS. 2 and 3, each of the first element 10A and the second element 10B may further include a second insulating member 42. The second insulating member 42 of the first element 10A is located between the third electrode 53 of the first element 10A and the second electrode 52 of the first element 10A, and between the fourth electrode 54 of the first element 10A. It is provided between the second electrode 52 of the first element 10A.

The second insulating member 42 of the second element 10B is located between the third electrode 53 of the second element 10B and the second electrode 52 of the second element 10B, and between the fourth electrode 54 of the second element 10B. It is provided between the second electrode 52 of the second element 10B.

In the embodiment, for example, a second impurity concentration of the first conductivity type in the second semiconductor region 12 is higher than a first impurity concentration of the first conductivity type in the first semiconductor region 11. For example, a fifth impurity concentration of the first conductivity type in the fifth semiconductor region 15 is higher than the first impurity concentration.

For example, a fourth impurity concentration of the second conductivity type in the fourth semiconductor region 14 is higher than a third impurity concentration of the second conductivity type in the third semiconductor region 13. For example, a sixth impurity concentration of the second conductivity type in the sixth semiconductor region 16 is higher than the third impurity concentration.

As shown in FIGS. 2 and 3, each of the first element 10A and the second element 10B may further include a fifth electrode 55. The fifth electrode 55 is electrically connected to the second electrode 52. A direction from a part of the fifth electrode 55 to a part of the first semiconductor region 11 is along the second direction D2. A direction from a part of the fifth electrode 55 to a part of the third semiconductor region 13 is along the second direction D2. A direction from a part of the fifth electrode 55 to a part of the fourth semiconductor region 14 is along the second direction D2. By providing the fifth electrode 55, for example, a high breakdown voltage can be easily obtained.

In the embodiment, information regarding the shape of the semiconductor region and the like can be obtained by, for example, electron microscopic observation. Information regarding the impurity concentration in the semiconductor region can be obtained by, for example, EDX (Energy Dispersive X-ray Spectroscopy) or SIMS (Secondary Ion Mass Spectrometry). Information regarding the carrier concentration in the semiconductor region can be obtained by, for example, SCM (Scanning Capacitance Microscopy).

The embodiments may include the following Technical proposals:

### (Technical Proposal 1)

A semiconductor device, comprising:
a first element;
a second element;
a first terminal;
a second terminal;
a third terminal;
a fourth terminal;
a fifth terminal;
a sixth terminal; and
a circuit section,
each of the first element and the second element including
a first electrode,
a second electrode,
a third electrode,
a fourth electrode, and
a semiconductor member provided between the first electrode and the second electrode,
a second direction from the third electrode to the fourth electrode crossing a first direction from the first electrode to the second electrode,
the semiconductor member including
   a first semiconductor region of a first conductivity type, the first semiconductor region including a first partial region, a second partial region, a third partial region, and a fourth partial region, a direction from the first partial region to the third electrode being along the first direction, a direction from the second partial region to the fourth electrode being along the first direction,
   a second semiconductor region of the first conductivity type, a direction from a part of the third electrode to the second semiconductor region being along the second direction, the second semiconductor region being connected to the second electrode,
   a third semiconductor region of a second conductivity type, a part of the third semiconductor region being between the third partial region and the second semiconductor region in the first direction, a direction from the part of the third electrode to the part of the third semiconductor region being along the second direction.
   a fourth semiconductor region of the second conductivity type, another part of the third semiconductor region being between the fourth partial region and the fourth semiconductor region in the first direction, a direction from the other part of the third semiconductor region to a part of the fourth electrode being along the second direction,
   a fifth semiconductor region of the first conductivity type provided between the first electrode and the first semiconductor region in the first direction, and
   a sixth semiconductor region of the second conductivity type provided between the first electrode and the first semiconductor region in the first direction, a direction from the fifth semiconductor region to the sixth semiconductor region being along a fourth direction, the fourth direction being along a plane including the second direction and a third direction, the third direction crossing a plane including the first direction and the second direction,
the first terminal being electrically connected to the second electrode of the first element,
the second terminal being electrically connected to the third electrode of the first element,
the third terminal being electrically connected to the fourth electrode of the first element,
the fourth terminal being electrically connected to the second electrode of the second element and the first electrode of the first element,
the fifth terminal being electrically connected to the third electrode of the second element,
the sixth terminal being electrically connected to the fourth electrode of the second element,
the circuit section being configured to set the second terminal to a first potential based on a potential of the first terminal in a first period,
the circuit section being configured to set the second terminal to a third potential based on the potential of the first terminal in a second period after the first period,
the circuit section being configured to set the second terminal to a second potential based on the potential of the first terminal in a third period after the second period, the second potential being lower than the first potential, the third potential being between the first potential and the second potential,
the circuit section being configured to set the third terminal to the first potential in the first period and the second period,
the circuit section being configured to set the third terminal to the second potential in the third period,
the circuit section being configured to set the fifth terminal and the sixth terminal to a fourth potential based on a potential of the fourth terminal in the first period and the second period, and
the circuit section being configured to set the fifth terminal and the sixth terminal to a fifth potential based on the potential of the fourth terminal in the third period, the fourth potential being lower than the fifth potential.

### (Technical Proposal 2)

The semiconductor device according to Technical proposal 1, further comprising:
a seventh terminal electrically connected to the first electrode of the second element,
the circuit section being configured to apply a controlled voltage between the first terminal and the seventh terminal.

### (Technical Proposal 3)

The semiconductor device according to Technical proposal 1 or 2, wherein the third potential is less than a threshold voltage of the first element.

### (Technical Proposal 4)

The semiconductor device according to any one of Technical proposals 1-3, wherein
a first absolute value of a first difference between the third potential and the first potential is not less than 0.8 times and not more than 1.2 times a second absolute value of a second difference between the third potential and the second potential.

### (Technical Proposal 5)

The semiconductor device according to any one of Technical proposals 1-4, wherein
the first potential is positive, and
the second potential is negative.

### (Technical Proposal 6)

The semiconductor device according to any one of Technical proposals 1-5, wherein
a second length of the second period is shorter than a first length of the first period.

### (Technical Proposal 7)

The semiconductor device according to Technical proposal 6, wherein
the second length is not less than 10 times and not more than 100 times the first length.

### (Technical Proposal 8)

The semiconductor device according to Technical proposal 6 or 7, wherein
the first length is not less than 10 μs and not more than 200 μs, and
the second length is not less than 1 μs and less than 10 μs.

### (Technical Proposal 9)

The semiconductor device according to any one of Technical proposals 1-8, wherein
a time when the fifth terminal and the sixth terminal become the fifth potential is the same as a time when the third terminal becomes the second potential.

### (Technical Proposal 10)

The semiconductor device according to any one of Technical proposals 1-8, wherein
the third terminal becomes the second potential after a time when the fifth terminal and the sixth terminal become the fifth potential, and
a length of a time between a time when the fifth terminal and the sixth terminal become the fifth potential and the time when the third terminal becomes the second potential is 1 μs or less.

### (Technical Proposal 11)

The semiconductor device according to any one of Technical proposals 1-10, wherein
each of the first element and the second element further includes a first insulating member,
the first insulating member of the first element is provided between the third electrode of the first element and the semiconductor member of the first element, and between the fourth electrode of the first element and the semiconductor member of the first element, and
the first insulating member of the second element is provided between the third electrode of the second element and the semiconductor member of the second element, and between the fourth electrode of the second element and the semiconductor member of the second element.

### (Technical Proposal 12)

The semiconductor device according to Technical proposal 11, wherein
a part of the first insulating member is in contact with a part of the third electrode and the second semiconductor region in the second direction.

### (Technical Proposal 13)

The semiconductor device according to Technical proposal 12, wherein
another part of the first insulating member is in contact with a part of the fourth electrode and the fourth semiconductor region in the second direction.

### (Technical Proposal 14)

The semiconductor device according to any one of Technical proposals 1-13, wherein
each of the first element and the second element further includes a second insulating member,
the second insulating member of the first element is provided between the third electrode of the first element and the second electrode of the first element, and between the fourth electrode of the first element and the second electrode of the first element, and
the second insulating member of the second element is provided between the third electrode of the second element and the second electrode of the second element, and between the fourth electrode of the second element and the second electrode of the second element.

### (Technical Proposal 15)

The semiconductor device according to any one of Technical proposals 1-14, wherein
a second impurity concentration of the first conductivity type in the second semiconductor region is higher than a first impurity concentration of the first conductivity type in the first semiconductor region.

### (Technical Proposal 16)

The semiconductor device according to Technical proposal 15, wherein
a fifth impurity concentration of the first conductivity type in the fifth semiconductor region is higher than the first impurity concentration.

### (Technical Proposal 17)

The semiconductor device according to any one of Technical proposals 1-16, wherein
a fourth impurity concentration of the second conductivity type in the fourth semiconductor region is higher than a third impurity concentration of the second conductivity type in the third semiconductor region.

### (Technical Proposal 18)

The semiconductor device according to Technical proposal 17, wherein
a sixth impurity concentration of the second conductivity type in the sixth semiconductor region is higher than the third impurity concentration.

### (Technical Proposal 19)

The semiconductor device according to any one of Technical proposals 1-18, wherein
the third electrode and the fourth electrode extend along a third direction crossing a plane including the first direction and the second direction.

### (Technical Proposal 20)

A semiconductor device, comprising:
a first element;
a second element;
a first terminal;
a second terminal;
a third terminal;
a fourth terminal;
a fifth terminal;
a sixth terminal; and
a circuit section,
each of the first element and the second element including
a first electrode,
a second electrode,
a third electrode,
a fourth electrode, and
a semiconductor member provided between the first electrode and the second electrode,
a second direction from the third electrode to the fourth electrode crossing a first direction from the first electrode to the second electrode,
the semiconductor member including
   a first semiconductor region of a first conductivity type, the first semiconductor region including a first partial region, a second partial region, a third partial region, and a fourth partial region, a direction from the first partial region to the third electrode being along the first direction, a direction from the second partial region to the fourth electrode being along the first direction,
   a second semiconductor region of the first conductivity type, a direction from a part of the third electrode to the second semiconductor region being along the second direction,
   a third semiconductor region of a second conductivity type, a part of the third semiconductor region being between the third partial region and the second semiconductor region in the first direction, a direction from the part of the third electrode to the part of the third semiconductor region being along the second direction.
   a fourth semiconductor region of the second conductivity type, another part of the third semiconductor region being between the fourth partial region and the fourth semiconductor region in the first direction, a direction from the other part of the third semiconductor region to a part of the fourth electrode being along the second direction,
   a fifth semiconductor region of the first conductivity type provided between the first electrode and the first semiconductor region in the first direction, and
   a sixth semiconductor region of the second conductivity type provided between the first electrode and the first semiconductor region in the first direction, a direction from the fifth semiconductor region to the sixth semiconductor region being along a fourth direction, the fourth direction being along a plane including the second direction and a third direction, the third direction crossing a plane including the first direction and the second direction,
the first terminal being electrically connected to the second electrode of the first element,
the second terminal being electrically connected to the third electrode of the first element,
the third terminal being electrically connected to the fourth electrode of the first element,
the fourth terminal being electrically connected to the second electrode of the second element and the first electrode of the first element,
the fifth terminal being electrically connected to the third electrode of the second element,
the sixth terminal being electrically connected to the fourth electrode of the second element,
the circuit section being configured to change a potential of the second terminal from a first potential toward a second potential from a first time,
the first potential being a potential based on a potential of the first terminal,
the second potential being a potential based on the potential of the first terminal,
the second potential being lower than the first potential,
the circuit section being configured to set the potential of the second terminal to the second potential at a second time after the first time,
the circuit section being configured to change the potential of the third terminal from the first potential to the second potential at the second time,
the circuit section being configured to change a potential of the fifth terminal and a potential of the sixth terminal from a fourth potential to a fifth potential at the second time,
the fourth potential being a potential based on a potential of the fourth terminal,
the fifth potential being a potential based on the potential of the fourth terminal,
the fourth potential being lower than the fifth potential,
a time period between the first time and the second time being longer than a time period for the potential of the third terminal to change from the first potential to the second potential, and
the time period between the first time and the second time is longer than a time period of a change of the potential from the fourth potential to the fifth potential at the potential of the fifth terminal and the sixth terminal.

According to the embodiment, a semiconductor device that can reduce loss can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor device such as elements, terminals, circuit sections, electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first element;
a second element;
a first terminal;
a second terminal;
a third terminal;
a fourth terminal;
a fifth terminal;
a sixth terminal; and
a circuit section,
each of the first element and the second element including a first electrode,
a second electrode,
a third electrode,
a fourth electrode, and
a semiconductor member provided between the first electrode and the second electrode,
a second direction from the third electrode to the fourth electrode crossing a first direction from the first electrode to the second electrode,
the semiconductor member including
a first semiconductor region of a first conductivity type, the first semiconductor region including a first partial region, a second partial region, a third partial region, and a fourth partial region, a direction from the first partial region to the third electrode being along the first direction, a direction from the second partial region to the fourth electrode being along the first direction,
a second semiconductor region of the first conductivity type, a direction from a part of the third electrode to the second semiconductor region being along the second direction, the second semiconductor region being connected to the second electrode,
a third semiconductor region of a second conductivity type, a part of the third semiconductor region being between the third partial region and the second semiconductor region in the first direction, a direction from the part of the third electrode to the part of the third semiconductor region being along the second direction.
a fourth semiconductor region of the second conductivity type, another part of the third semiconductor region being between the fourth partial region and the fourth semiconductor region in the first direction, a direction from the other part of the third semiconductor region to a part of the fourth electrode being along the second direction,
a fifth semiconductor region of the first conductivity type provided between the first electrode and the first semiconductor region in the first direction, and
a sixth semiconductor region of the second conductivity type provided between the first electrode and the first semiconductor region in the first direction, a direction from the fifth semiconductor region to the sixth semiconductor region being along a fourth direction, the fourth direction being along a plane including the second direction and a third direction, the third direction crossing a plane including the first direction and the second direction,
the first terminal being electrically connected to the second electrode of the first element,
the second terminal being electrically connected to the third electrode of the first element,
the third terminal being electrically connected to the fourth electrode of the first element,
the fourth terminal being electrically connected to the second electrode of the second element and the first electrode of the first element,
the fifth terminal being electrically connected to the third electrode of the second element,
the sixth terminal being electrically connected to the fourth electrode of the second element,
the circuit section being configured to set the second terminal to a first potential based on a potential of the first terminal in a first period,
the circuit section being configured to set the second terminal to a third potential based on the potential of the first terminal in a second period after the first period,
the circuit section being configured to set the second terminal to a second potential based on the potential of the first terminal in a third period after the second period, the second potential being lower than the first potential, the third potential being between the first potential and the second potential,
the circuit section being configured to set the third terminal to the first potential in the first period and the second period,
the circuit section being configured to set the third terminal to the second potential in the third period,
the circuit section being configured to set the fifth terminal and the sixth terminal to a fourth potential based on a potential of the fourth terminal in the first period and the second period, and
the circuit section being configured to set the fifth terminal and the sixth terminal to a fifth potential based on the potential of the fourth terminal in the third period, the fourth potential being lower than the fifth potential.

2. The device according to claim 1, further comprising:
a seventh terminal electrically connected to the first electrode of the second element,
the circuit section being configured to apply a controlled voltage between the first terminal and the seventh terminal.

3. The device according to claim 1, wherein
the third potential is less than a threshold voltage of the first element.

4. The device according to claim 1, wherein
a first absolute value of a first difference between the third potential and the first potential is not less than 0.8 times and not more than 1.2 times a second absolute value of a second difference between the third potential and the second potential.

5. The device according to claim 1, wherein
the first potential is positive, and
the second potential is negative.

6. The device according to claim 1, wherein
a second length of the second period is shorter than a first length of the first period.

7. The device according to claim 6, wherein
the second length is not less than 10 times and not more than 100 times the first length.

8. The device according to claim 6, wherein
the first length is not less than 10 μs and not more than 200 μs, and
the second length is not less than 1 μs and less than 10 μs.

9. The device according to claim 1, wherein
a time when the fifth terminal and the sixth terminal become the fifth potential is the same as a time when the third terminal becomes the second potential.

10. The device according to claim 1, wherein
the third terminal becomes the second potential after a time when the fifth terminal and the sixth terminal become the fifth potential, and
a length of a time between a time when the fifth terminal and the sixth terminal become the fifth potential and the time when the third terminal becomes the second potential is 1 μs or less.

11. The device according to claim 1, wherein
each of the first element and the second element further includes a first insulating member,
the first insulating member of the first element is provided between the third electrode of the first element and the semiconductor member of the first element, and between the fourth electrode of the first element and the semiconductor member of the first element, and
the first insulating member of the second element is provided between the third electrode of the second element and the semiconductor member of the second element, and between the fourth electrode of the second element and the semiconductor member of the second element.

12. The device according to claim 11, wherein
a part of the first insulating member is in contact with a part of the third electrode and the second semiconductor region in the second direction.

13. The device according to claim 12, wherein
another part of the first insulating member is in contact with a part of the fourth electrode and the fourth semiconductor region in the second direction.

14. The device according to claim 1, wherein
each of the first element and the second element further includes a second insulating member,
the second insulating member of the first element is provided between the third electrode of the first element and the second electrode of the first element, and between the fourth electrode of the first element and the second electrode of the first element, and
the second insulating member of the second element is provided between the third electrode of the second element and the second electrode of the second element, and between the fourth electrode of the second element and the second electrode of the second element.

15. The device according to claim 1, wherein
a second impurity concentration of the first conductivity type in the second semiconductor region is higher than a first impurity concentration of the first conductivity type in the first semiconductor region.

16. The device according to claim 15, wherein
a fifth impurity concentration of the first conductivity type in the fifth semiconductor region is higher than the first impurity concentration.

17. The device according to claim 1, wherein
a fourth impurity concentration of the second conductivity type in the fourth semiconductor region is higher than a third impurity concentration of the second conductivity type in the third semiconductor region.

18. The device according to claim 17, wherein
a sixth impurity concentration of the second conductivity type in the sixth semiconductor region is higher than the third impurity concentration.

19. The device according to claim 1, wherein
the third electrode and the fourth electrode extend along a third direction crossing a plane including the first direction and the second direction.

20. A semiconductor device, comprising:
a first element;
a second element;
a first terminal;
a second terminal;
a third terminal;
a fourth terminal;
a fifth terminal;
a sixth terminal; and
a circuit section,
each of the first element and the second element including a first electrode,
a second electrode,
a third electrode,
a fourth electrode, and
a semiconductor member provided between the first electrode and the second electrode,
a second direction from the third electrode to the fourth electrode crossing a first direction from the first electrode to the second electrode,
the semiconductor member including
a first semiconductor region of a first conductivity type, the first semiconductor region including a first partial region, a second partial region, a third partial region, and a fourth partial region, a direction from the first partial region to the third electrode being along the first direction, a direction from the second partial region to the fourth electrode being along the first direction,
a second semiconductor region of the first conductivity type, a direction from a part of the third electrode to the second semiconductor region being along the second direction,
a third semiconductor region of a second conductivity type, a part of the third semiconductor region being between the third partial region and the second semiconductor region in the first direction, a direction from the part of the third electrode to the part of the third semiconductor region being along the second direction,
a fourth semiconductor region of the second conductivity type, another part of the third semiconductor region being between the fourth partial region and the fourth semiconductor region in the first direction, a direction from the other part of the third semiconductor region to a part of the fourth electrode being along the second direction,
a fifth semiconductor region of the first conductivity type provided between the first electrode and the first semiconductor region in the first direction, and
a sixth semiconductor region of the second conductivity type provided between the first electrode and the first semiconductor region in the first direction, a direction from the fifth semiconductor region to the sixth semiconductor region being along a fourth direction, the fourth direction being along a plane including the second direction and a third direction, the third direction crossing a plane including the first direction and the second direction,
the first terminal being electrically connected to the second electrode of the first element,
the second terminal being electrically connected to the third electrode of the first element,
the third terminal being electrically connected to the fourth electrode of the first element,
the fourth terminal being electrically connected to the second electrode of the second element and the first electrode of the first element,
the fifth terminal being electrically connected to the third electrode of the second element,
the sixth terminal being electrically connected to the fourth electrode of the second element,
the circuit section being configured to change a potential of the second terminal from a first potential toward a second potential from a first time,
the first potential being a potential based on a potential of the first terminal,
the second potential being a potential based on the potential of the first terminal,
the second potential being lower than the first potential,
the circuit section being configured to set the potential of the second terminal to the second potential at a second time after the first time,
the circuit section being configured to change the potential of the third terminal from the first potential to the second potential at the second time,
the circuit section being configured to change a potential of the fifth terminal and a potential of the sixth terminal from a fourth potential to a fifth potential at the second time,
the fourth potential being a potential based on a potential of the fourth terminal,
the fifth potential being a potential based on the potential of the fourth terminal,
the fourth potential being lower than the fifth potential,
a time period between the first time and the second time being longer than a time period for the potential of the third terminal to change from the first potential to the second potential, and
the time period between the first time and the second time is longer than a time period of a change of the potential from the fourth potential to the fifth potential at the potential of the fifth terminal and the sixth terminal.
